(19) United States
(12) Patent Application Publication
(10) Pub. No.: US 2024/0266423 A1
(43) Pub. Date: Aug. 8, 2024

(54) FORMING OF AN ELECTRONIC POWER COMPONENT

(71) Applicant: STMicroelectronics International N.V., Geneva (CH)

(72) Inventor: Benjamin MORILLON, Tours (FR)

(73) Assignee: STMicroelectronics International N.V., Geneva (CH)

(21) Appl. No.: 18/420,600

(22) Filed: Jan. 23, 2024

(30) Foreign Application Priority Data
Feb. 8, 2023 (FR) 2301163

(51) Int. Cl. H01L 29/747; H01L 21/02; H01L 21/28; H01L 29/66; H01L 21/304

(52) U.S. Cl. CPC H01L 29/747; H01L 21/02323; H01L 21/28035; H01L 29/66386; H01L 21/3043

(57) ABSTRACT

The present disclosure concerns a method of forming an electronic power component inside and on top of a semiconductor substrate, comprising the following successive steps: a) forming of a peripheral groove in the semiconductor substrate on the side of a first surface of the semiconductor substrate; b) deposition of an oxygen-doped polysilicon layer, on top of and in contact with the bottom and the lateral walls of the peripheral groove and with the first surface of the semiconductor substrate; c) local deposition of a glass layer, on the oxygen-doped polysilicon layer, the glass layer extending in the peripheral groove and further extending over a portion of the first surface of the semiconductor substrate; and d) etching of the oxygen-doped polysilicon layer so that it extends on the first surface of the semiconductor substrate beyond the glass layer.

### CROSS-REFERENCE TO RELATED APPLICATION(S)

This application claims the priority benefit of French patent application number 2301163, filed on Feb. 8, 2023, entitled “Formation d'un composant électronique de puissance” which is hereby incorporated by reference to the maximum extent allowable by law.

### BACKGROUND

### Technical Field

The present disclosure generally concerns semiconductor electronic components and more particularly electronic power components such as thyristors and triacs.

### Description of the Related Art

Different technologies of power components and different techniques for manufacturing these components are known. The MESA technology, which comprises surrounding a PN junction, formed in the entire surface of the component, with a groove filled with glass on at least a surface of the component as a termination of the junction, is particularly known.

There exists a use for improving electronic power components, particularly MESA technology electronic components, and their manufacturing techniques. More particularly, there is a use for stabilizing leakage currents and/or to increase the breakdown voltage in these components.

### BRIEF SUMMARY

To achieve this, an embodiment provides a method of forming an electronic power component inside and on top of a semiconductor substrate, comprising the following successive steps:
a) forming of a peripheral groove in the semiconductor substrate on the side of a first surface of the semiconductor substrate;
b) deposition of an oxygen-doped polysilicon layer, on top of and in contact with the bottom and the lateral walls of the peripheral groove and with said first surface of the semiconductor substrate;
c) local deposition of a glass layer, on the oxygen-doped polysilicon layer, the glass layer extending in the peripheral groove and further extending over a portion of said first surface of the semiconductor substrate; and
d) etching of the oxygen-doped polysilicon layer so that it extends on said first surface of the semiconductor substrate beyond the glass layer.

According to an embodiment, the method comprises, between steps b) and c), a step e) of deposition of an electrically-insulating layer on top of and in contact with the oxygen-doped polysilicon layer.

According to an embodiment, the method comprises, between steps c) and d), a step e) of deposition of an electrically-insulating layer on top of and in contact with the glass layer and a portion of the oxygen-doped polysilicon layer not covered with the glass layer.

According to an embodiment, the electrically-insulating layer is etched, at the same time as the oxygen-doped polysilicon layer, during step d).

According to an embodiment, the deposition of the glass layer during step c) is performed by silk-screening.

According to an embodiment, the groove has a depth greater than 75 μm.

According to an embodiment, the oxygen-doped polysilicon layer has a thickness in the range from 0.1 μm to 2 μm.

Another embodiment provides an electronic power component, comprising:
a peripheral groove formed in a semiconductor substrate on the side of a first surface of the semiconductor substrate;
an oxygen-doped polysilicon layer, formed on top of and in contact with the bottom and the lateral walls of the peripheral groove and with said first surface of the semiconductor substrate; and
a glass layer, formed on the oxygen-doped polysilicon layer, the glass layer extending in the peripheral groove and further extending on a portion of said first surface of the semiconductor substrate and the oxygen-doped polysilicon layer extending on said first surface of the semiconductor substrate beyond the glass layer.

According to an embodiment, the component comprises an electrically-insulating layer between the oxygen-doped polysilicon layer and the glass layer, the electrically-insulating layer being in contact, by a first surface, with the oxygen-doped polysilicon layer and, by a second surface opposite to the first surface, with the glass layer.

According to an embodiment, the component comprises an electrically-insulating layer, the glass layer being in contact, by a first surface, with the electrically-insulating layer and, by a second surface opposite to the first surface, with the oxygen-doped polysilicon layer and the electrically-insulating layer being in contact with a portion of the oxygen-doped polysilicon layer not covered with the glass layer.

According to an embodiment, the groove has a depth greater than 75 μm.

According to an embodiment, the oxygen-doped polysilicon layer has a thickness in the range from 0.1 μm to 2 μm.

Another embodiment provides a power control circuit comprising an electronic power as described.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A, FIG. 1B, FIG. 1C, FIG. 1D, and FIG. 1E show, in partial simplified cross-section views, successive steps of an example of a method of manufacturing a power component according to a first embodiment; and

FIG. 2A, FIG. 2B, FIG. 2C, and FIG. 2D show, in partial simplified cross-section views, successive steps of an example of a method of manufacturing a power component according to a second embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, only the forming of the peripheral insulating grooves of the component, and of the passivation layers formed in these grooves, taking part in the leakage current decrease and in the increase of the breakdown voltage of the component, has been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

Electronic power components generally comprise a semiconductor substrate comprising at least one horizontal planar PN junction laterally surrounded with a peripheral groove extending vertically in the substrate. To limit leakage currents and/or to increase the breakdown voltage, the vertical electronic power components may comprise a passivation structure covering the sides and the bottom of the groove and a portion of a surface of the semiconductor substrate, at the groove surface. The passivation structure may for example comprise a layer of oxygen-doped polysilicon or SIPOS (“Semi-Insulating Polycrystalline Silicon”). The passivation structure may further comprise a glass layer formed on the SIPOS layer and more precisely formed in the groove and on said surface of the semiconductor substrate, at the groove surface, so that it entirely covers the SIPOS layer.

In electronic power components, the groove depth generates a complexity in the etching of the SIPOS layer, which is performed before the forming of the glass layer. More particularly, it generates a complexity in the forming of the masking resin through which the SIPOS layer is etched, particularly its structuring by photolithography. Indeed, the deposition of the masking resin is not uniform and a significant quantity of resin has to be deposited so that the top of the groove is covered with the resin. In certain cases, the resin thickness on the upper surface of the substrate is such that a single photolithography step does not enable to locally illuminate it across its entire thickness. For example, in the case of electronic power components with a very high breakdown voltage (for example, greater than or equal to 1,200 V), the depth of the groove may be greater than some hundred micrometers and the thickness of the masking resin may reach several tens of micrometers. Thus, a plurality of cycles of deposition and then of illumination of the resin may be necessary to obtain the desired thickness. This results in an increased complexity and in an increase in the component manufacturing cost.

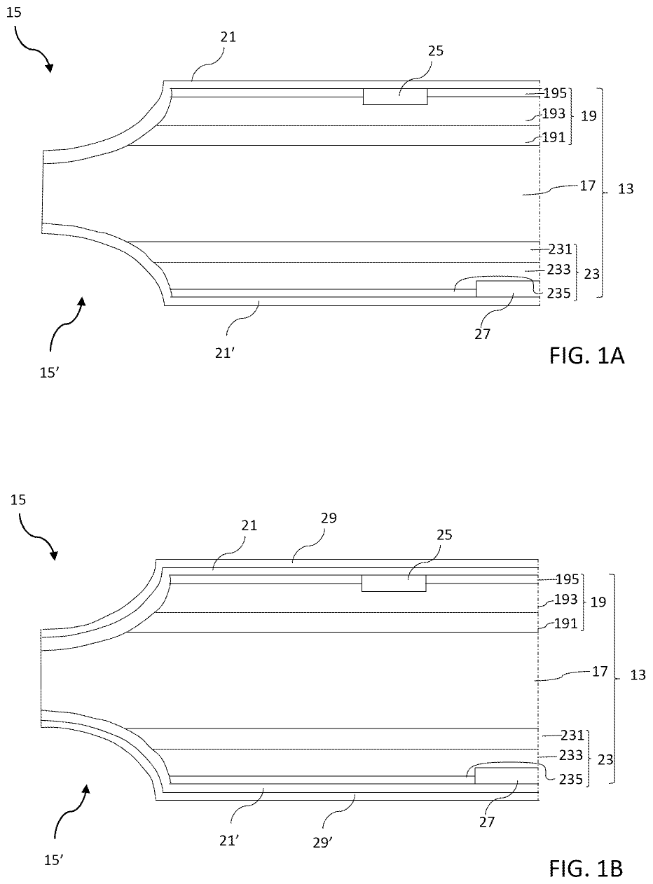

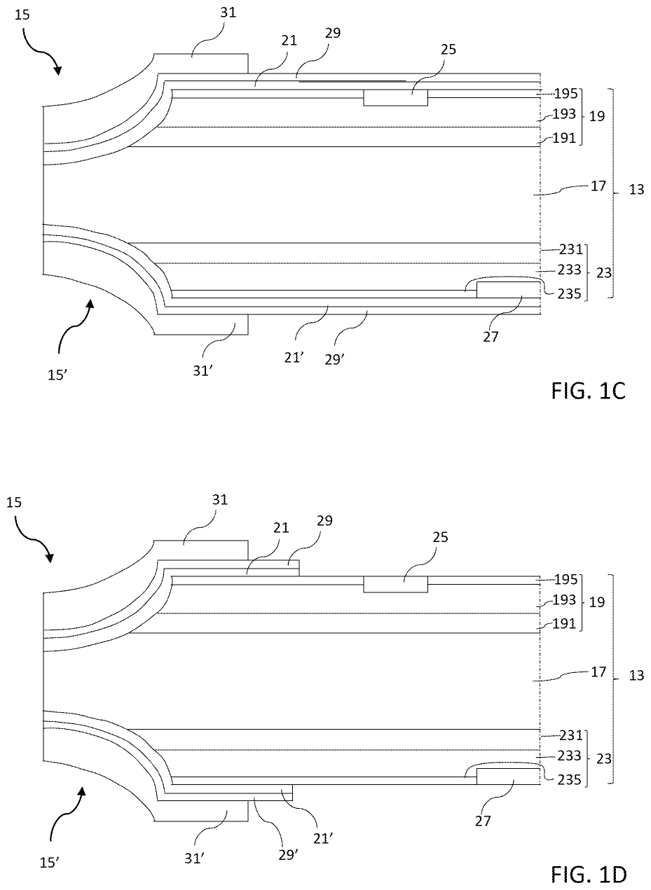

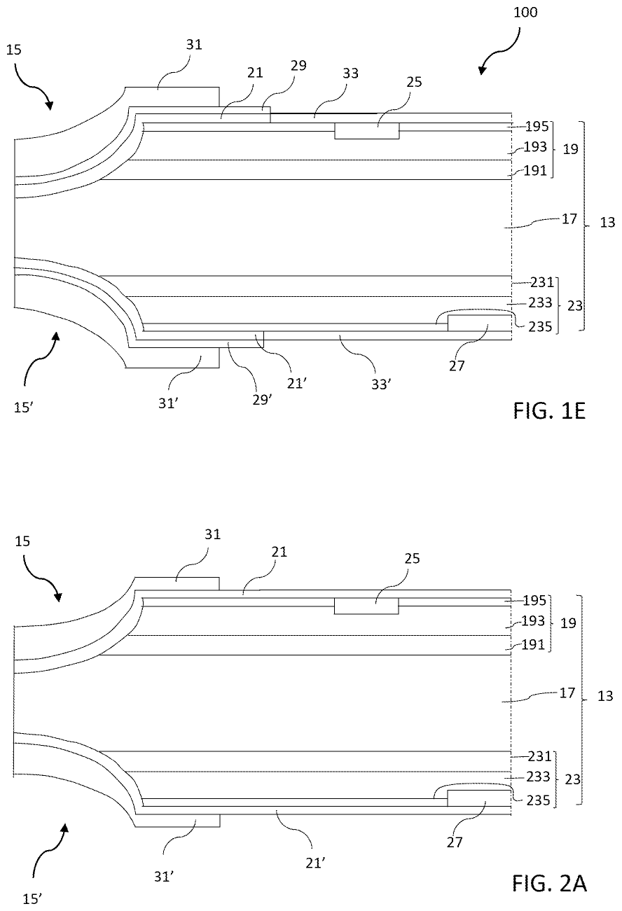

FIG. 1A, FIG. 1B, FIG. 1C, FIG. 1D, and FIG. 1E show, in partial simplified cross-section views, successive steps of an example of a power component manufacturing method according to a first embodiment. FIGS. 1A to 1E more particularly illustrate an example of a method of manufacturing a peripheral passivation structure of a power component according to the first embodiment. It should be noted that in the drawings, the forming of a single component is shown. In practice, a plurality of components may be simultaneously formed inside and on top of a same semiconductor substrate, the substrate being then cut into individual chips, each comprising a single electronic power component.

The described power electronic components can, for example, be used in various power control, power conversion, or power matching circuits, such as in industrial equipment, display or lighting devices, telecommunications equipment, home appliance equipment, automotive device, etc.

FIG. 1A shows an initial structure comprising a semiconductor substrate 13 in which is formed, on its upper surface side, a peripheral groove 15 laterally surrounding a horizontal planar PN junction of the component. In FIG. 1A, only a portion of the initial structure has been shown. In practice, the structure extends beyond the right edge shown in dotted lines in FIG. 1A, peripheral groove 15 surrounding the structure.

The component for example has, in top view, a square or rectangular general shape, for example, with rounded corners, or circular. Substrate 13 is for example made of silicon.

As an example, substrate 13 comprises a central portion 17, for example doped with a first conductivity type, for example, N-type doped. As an example, substrate 13 further comprises an upper portion 19, for example, doped with a second conductivity type different from the first conductivity type, for example, P-type doped. As an example, upper portion 19 is in contact, by its lower surface, with the upper surface of the central portion 17 of substrate 13.

The upper portion 19 of substrate 13 for example comprises an increasing doping gradient from its lower surface. Further, the upper portion 19 of substrate 13 for example comprises a plurality of different dopant elements.

As an example, the upper portion 19 of substrate 13 comprises a first portion 191 in contact, by its lower surface, with the upper surface of portion 17 of substrate 13. First portion 191 is for example doped with aluminum atoms.

Further, the upper portion 19 of substrate 13 for example comprises a second portion 193, in contact, by its lower surface, with the upper surface of portion 191. Second portion 193 is for example doped with gallium atoms.

As an example, the upper portion 19 of substrate 13 further comprises a third portion 195, in contact, by its lower surface, with the upper surface of portion 193. Third portion 195 is for example doped with gallium atoms.

As an example, the groove 15 formed on the upper surface of the initial structure extends from the upper surface of the upper portion 19 of substrate 13 into substrate 13 and emerges into the first portion 17 of substrate 13. The groove thus extends, for example through portions 195, 193, and 191. Thus, groove 15 crosses the PN junction formed by the horizontal plane of interface between upper and central portions 19 and 17.

The depth of groove 15 from the upper surface of substrate 13 is for example greater than 30 μm, for example greater than 75 μm, for example greater than 105 μm, for example in the range from 105 μm to 150 μm.

The structure of FIG. 1A further comprises a layer of oxygen-doped polysilicon or SIPOS (“Semi-Insulating Polycrystalline Silicon”) 21, extending on the walls and the bottom of grooves 15 and on top of and in contact with the upper surface of substrate 13, at the surface of grooves 15. As an example, SIPOS layer 21 has an oxygen content in the range from 10% to 50%, for example from 20% to 40%.

SIPOS layer 21 is for example deposited at the surface of substrate 13 and in grooves 15 by a chemical vapor deposition method, for example, a low-pressure chemical vapor deposition or LPCVD method. As an example, SIPOS layer 21 has a thickness in the range from 0.1 μm to 2 μm, for example in the range from 0.1 μm to 1 μm, for example in the order of 0.5 μm.

The initial structure illustrated in FIG. 1A is for example horizontally symmetrical. Substrate 13 for example comprises a lower portion 23 comprising portions 231, 233, and 235 for example respectively similar to the portions 191, 193, and 195 of upper portion 19. The structure for example comprises a groove 15′ formed from the lower surface of substrate 13. As an example, groove 15′ extends in lower portion 23 and emerges into the central portion 17 of substrate 13. The initial structure for example comprises another SIPOS layer 21′ extending on top of and in contact with the lower surface of substrate 13 and on the walls and the bottom of the groove 15′ formed from the lower surface of substrate 13. Thus, groove 15′ crosses the PN junction formed by the horizontal plane of interface between the lower and central portions 23 and 17 of the substrate.

The initial structure further comprises a local doped area 25 on the upper surface side of substrate 13, flush with this same surface. The structure can further comprise a local doped area 27 on the lower surface side of substrate 13, flush with this same surface.

As an example, layers 17, 19, and 23 each extend over the entire surface of the substrate. Areas 25 and 27 are respectively located on a portion only of the surface of the substrate.

Areas 25 and 27 are for example doped with the first conductivity type, for example, type N. As an example, areas 25 and 27 are more heavily doped than the central portion 17 of substrate 13 and than portions 195 and 235 of substrate 13. As an example, areas 25 and 27 are doped with phosphorus atoms.

The initial structure is thus formed of a first vertical stack of four regions 19, 17, 23, and 27 alternately P and N doped, and of a second vertical stack of four regions 25, 19, 17, and 23 alternately N and P doped, which define a triac. The described embodiments are not limited to this example of component. As an example, the region 27 can be omitted in the case of a thyristor-type structure. More generally, the described embodiments may be applied to any electronic power component called vertical, comprising a horizontal PN junction and a passivation structure formed in a peripheral insulating groove vertically crossing the PN junction.

FIG. 1B illustrates a structure obtained at the end of a step of forming of an electrically-insulating layer 29 on the upper surface of the structure illustrated in FIG. 1A. In this example, an electrically-insulating layer 29′ is further formed on the lower surface of the structure.

More particularly, during this step, layer 29 is formed continuously, that is, it is formed over the entire upper surface of the structure illustrated in FIG. 1A. During this step, layer 29 is formed in contact with SIPOS layer 21. Layer 29 for example covers the upper surface of layer 21 located on the sides and in the bottom of groove 15 and extending at the surface of groove 15.

Similarly, layer 29′ is formed continuously, that is, it is formed over the entire lower surface of the structure illustrated in FIG. 1A. During this step, layer 29′ is formed in contact with SIPOS layer 21′. Layer 29′ for example covers the lower surface of layer 21′ located on the sides and in the bottom of groove 15′ and extending at the surface of groove 15′.

As an example, layers 29 and 29′ are made of undoped glass, for example, undoped silicon glass (USG) or of undoped phosphosilicate glass (PSG). Layers 29 and 29′ are for example deposited by a chemical vapor deposition method, for example, by a LPCVD deposition method. As an example, layers 29 and 29′ have a thickness in the range from 0.1 μm to 1.5 μm, for example in the range from 0.5 μm to 1 μm.

FIG. 1C illustrates a structure obtained at the end of a step of forming of a glass layer 31 on the upper surface of the structure illustrated in FIG. 1B. In this example, a glass layer 31′ is further formed on the lower surface of the structure.

More particularly, during this step, layer 31 is formed locally at the surface of layer 29 and, for example, in contact therewith. Layer 31 thus covers the layer 29 located in the bottom and on the sides of groove 15 and at the surface of groove 15 without extending over the entire surface of layer 29 at the surface of groove 15.

Similarly, during this step, layer 31′ is formed locally at the surface of layer 29′ and, for example in contact therewith. Layer 31′ thus covers the layer 29′ located in the bottom and on the sides of groove 15′ and at the surface of groove 15′ without extending over the entire surface of layer 29′ at the surface of groove 15′.

Layers 31 and 31′ are deposited by a local deposition method, for example, by silk screening. This step for example consists in the deposition of a glass paste through a mask located at the surface of layer 29 or of layer 29′. As an example, after this deposition, layers 31 and 31′ undergo one or a plurality of annealing steps. The annealing step may for example comprise a step of pyrolysis at a temperature in the range from 300° C. to 700° C., for example, in the order of 500° C. The annealing step may further comprise a step of sintering at a temperature in the range from 500° C. to 1,000° C., for example in the order of 800° C.

As an example, layers 31 and 31′ have a non-constant thickness across their entire surfaces. It is for example greater at the bottom of grooves 15 and 15′ (that is, in the grooves of the wafer between components) than at their top and at the surface of grooves 15 and 15′.

The thickness of layers 31 and 31′ at the surface of substrate 13 at the periphery of grooves 15 and 15′ is for example in the range from 10 μm to 40 μm, for example in the range from 20 μm to 30 μm.

The thickness of layers 31 and 31′ in the bottom of grooves 15 and 15′ is for example in the range from 20 μm to 70 μm, for example in the range from 40 μm to 50 μm.

FIG. 1D illustrates a structure obtained at the end of a step of local removal of the layers 21 and 29 and of the layers 21′ and 29′ of the structure illustrated in FIG. 1C.

During this step, there is for example first formed by photolithography a masking layer (not shown) made of a resist on the upper surface of the structure illustrated in FIG. 1C.

As an example, the resist of the masking layer is deposited by spin coating, exposed to UVs, and then developed in a solvent. As an example, the masking layer covers the entire surface of the glass layer 31. The masking layer extends laterally beyond the glass layer 31, and thereby covering a portion of layers 21 and 29 in the vicinity of the glass layer 31. However, the masking layer doesn't cover layers 21 and 29 in front of a central portion of the component.

During this step, and at a second step, layers 21 and 29 are etched through the masking layer. As an example, the etching of layers 21 and 29 is a wet etching.

Similarly, there is for example also during this step formed by photolithography a masking layer (not shown) made of a resist on the lower surface of the structure illustrated in FIG. 1C and etched layers 21′ and 29′ through the masking layer.

At the end of this step, layers 21 and 29 extend, for example, in the bottom and on the sides of grooves 15 and at the surface of groove 15 over a portion of the upper surface of substrate 13. As an example, layers 21 and 29 extend on the upper surface of substrate 13 beyond glass layer 31, that is, layers 21 and 29 extend on substrate 13 in the entire location in front of glass layer 31 and further extends over a portion of substrate 13 outside of the location in front of glass layer 31. As an example, at the end of this step, layers 21 and 29 do not cover area 25.

Similarly, layers 21′ and 29′ extend, for example, in the bottom and on the sides of grooves 15′ and at the surface of groove 15′ over a portion of the lower surface of substrate 13. As an example, layers 21′ and 29′ extend on the lower surface of substrate 13 beyond glass layer 31′, that is, layers 21′ and 29′ extend on substrate 13 all over the location in front of glass layer 31′ and further extends on a portion of substrate 13 outside of glass layer 31′. As an example, at the end of this step, layers 21′ and 29′ do not cover area 27.

FIG. 1E illustrates a structure obtained at the end of a step of forming electrically-conductive layers 33 and 33′ respectively on the upper and lower surfaces of the structure illustrated in FIG. 1D.

More particularly, during this step, there is for example formed an electrically-conductive layer 33 as an extension of layers 21 and 29 at the surface of substrate 13. As an example, layer 33 is formed in contact with a portion of the upper surface of substrate 13 not covered with layers 21 and 29. As an example, layer 33 extends from layers 21 and 29 and is, for example, in contact by its side with the side of layers 21 and 29.

Similarly, during this step, there is also for example formed an electrically-conductive layer 33′ as an extension of layers 21′ and 29′ at the surface of substrate 13. As an example, layer 33′ is formed in contact with a portion of the lower surface of substrate 13 not covered with layers 21′ and 29′. As an example, layer 33′ extends from layers 21′ and 29′ and is, for example, in contact by its side with the side of layers 21′ and 29′.

As an example, layers 33 and 33′ are made of a metallic material, for example of gold and/or of nickel. As an example, layers 33 and 33′ are formed by wet deposition, for example by an electroless chemical deposition.

In this step, the deposit is formed only on the conductive portions of the structure and is not formed on the insulating portions of the structure. Layers 33 and 33′ are then selectively formed in contact with the exposed semiconductor portions of the structure illustrated in FIG. 1D. Layers 33 and 33′ are then respectively formed in contact with the upper surface and the lower surface of substrate 13. As an example, layers 29 and 29′ enable, during this step, to respectively protect the upper surface of layer 21 and the lower surface of layer 21′ from the deposition of layers 33 and 33′. Layers 29 and 29′ particularly enable to respectively protect layers 21 and 21′ from the deposition of layers 33 and 33′. Indeed, in the absence of layers 29 and 29′, layers 33 and 33′ would tend to further form over a portion of layers 21 and 21′ which are semi-insulating.

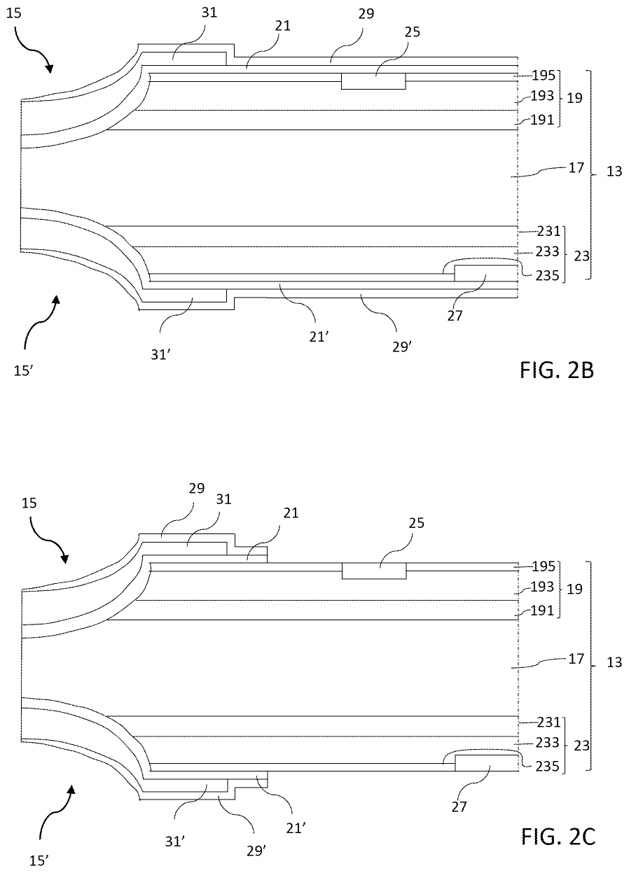

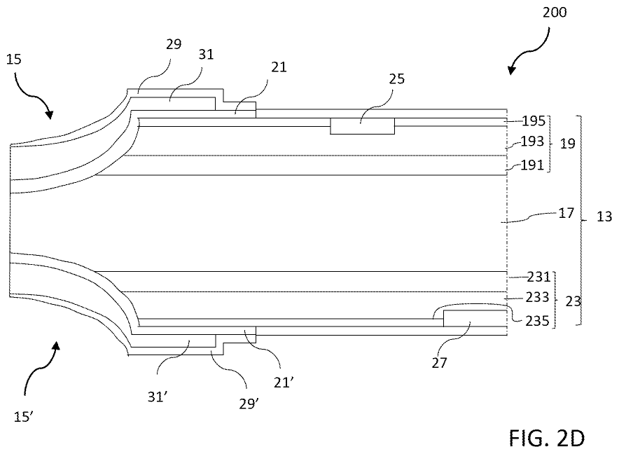

FIG. 2A, FIG. 2B, FIG. 2C, and FIG. 2D show, in partial simplified cross-section views, successive steps of an example of a power component manufacturing method according to a second embodiment.

More particularly, FIGS. 2A to 2D illustrate the power component manufacturing method according to a second embodiment. The method of FIGS. 2A to 2D differs from the method of FIGS. 1A to 1E essentially in that, in the method of FIGS. 2A to 2D, electrically-insulating layer 29 is formed after glass layer 31.

FIG. 2A illustrates a structure obtained at the end of a step of forming of glass layers 31 and 31′ respectively on the upper and lower surfaces of the structure illustrated in FIG. 1A.

The step of forming of glass layers 31 and 31′ illustrated in FIG. 2A is for example similar to the step of forming of glass layers 31 and 31′ illustrated in FIG. 1C with the difference that, in FIG. 2A, glass layers 31 and 31′ are respectively formed on top of and in contact with SIPOS layers 21 and 21′.

During this step, layer 31 is thus locally formed at the surface of layer 21 and for example in contact therewith. Layer 31 thus covers the layer 21 located in the bottom and on the sides of groove 15 and at the surface of groove 15 without extending over the entire surface of layer 21 at the surface of groove 15.

Similarly, during this step, layer 31′ is locally formed at the surface of layer 21′ and for example in contact therewith. Layer 31′ thus covers the layer 21′ located in the bottom and on the sides of groove 15′ and at the surface of groove 15′ without extending over the entire surface of layer 21′ at the surface of groove 15′.

FIG. 2B illustrates a structure obtained at the end of a step of forming of electrically-insulating layers 29 and 29′ respectively on the upper and lower surfaces of the structure illustrated in FIG. 2A.

The step of forming of electrically-insulating layers 29 and 29′ illustrated in FIG. 2B is for example similar to the step of forming of electrically-insulating layers 29 and 29′ illustrated in FIG. 1B with the difference that, in FIG. 2B, electrically-insulating layer 29 is formed on top of and in contact with glass layer 31 and with the portion of SIPOS layer 21 not covered with glass layer 31. Further, the step of forming of electrically-insulating layers 29 and 29′ illustrated in FIG. 2B differs from the step of forming of electrically-insulating layers 29 and 29′ illustrated in FIG. 1B in that, in FIG. 2B, electrically-insulating layer 29′ is formed on top of and in contact with glass layer 31′ and with the portion of SIPOS layer 21′ not covered with glass layer 31′.

Layer 29 thus covers the upper surface of the glass layer 31 located on the sides and in the bottom of groove 15 and extending at the surface of groove 15 and further covers the portion of the upper surface of layer 21 at the surface of groove 15 not covered with layer 31. As an example, layer 29 covers the side of glass layer 31 at the surface of groove 15. As an example, at the end of this step, glass layer 31 is in contact, by its lower surface, with the upper surface of SIPOS layer 21 and, by its upper surface, with the lower surface of layer 29.

Similarly, layer 29′ thus covers the lower surface of glass layer 31′ located on the sides and in the bottom of groove 15′ and extending at the surface of groove 15′ and further covers the portion of the lower surface of layer 21′ at the surface of groove 15′ not covered with glass layer 31′. As an example, layer 29′ covers the side of glass layer 31′ at the surface of groove 31′. As an example, at the end of this step, glass layer 31′ is in contact, by its upper surface, with the lower surface of SIPOS layer 21′ and, by its lower surface, with the upper surface of layer 29′.

FIG. 2C illustrates a structure obtained at the end of a step of structuring or local removal of the layers 21 and 29 and of the layers 21′ and 29′ of the structure illustrated in FIG. 2B.

The step of structuring of layers 21 and 29 and of layers 21′ and 29′ illustrated in FIG. 2C is for example similar to the step of structuring of layers 21 and 29 and of layers 21′ and 29′ illustrated in FIG. 1D with the difference that, in FIG. 2C, the masking layers enabling to etch layers 21 and 29 and layers 21′ and 29′ are respectively formed on top of and in contact with the upper surface of layer 29 and on top of and in contact with the lower surface of layer 29′.

FIG. 2D illustrates a structure obtained at the end of a step of forming of electrically-conductive layers 33 and 33′ respectively on the upper and lower surfaces of the structure illustrated in FIG. 2C.

The step of forming of layers 33 and 33′ illustrated in FIG. 2D is for example identical to the step of forming of layers 33 and 33′ illustrated in FIG. 1E.

An advantage of the described embodiments is that they enable to do away with one or a plurality of photolithography steps and thus to decrease the manufacturing costs of the considered electronic component. In particular, the local deposition of glass layers 31, 31′ enables to do away with a step of local etching of said glass layers.

Further, the step of local removal of passivation layers 21, 29 and, if present, 21′, 29′, is implemented after the deposition of glass 31, 31′ in grooves 15, 15′. Thus, during this step, grooves 15, 15′ are at least partially filled with glass 31, 31′. As a result, a decreased thickness of masking resist may be used for the step of local etching of layers 21, 29 and 21′, 29′. This enables to simplify this local etch step and to decrease its cost.

Various embodiments and variants have been described. Those skilled in the art will understand that certain features of these various embodiments and variants may be combined, and other variants will occur to those skilled in the art. In particular, the described embodiments are for example not limited to the examples of dimensions and of materials mentioned hereabove.

Further, although the embodiments have been described for a triac, the present disclosure may apply to any device comprising a peripheral mesa groove passivated with a glass layer and a SIPOS layer.

Finally, the practical implementation of the described embodiments and variations is within the abilities of those skilled in the art based on the functional indications given hereabove.

A method of forming an electronic power component (100; 200) inside and on top of a semiconductor substrate (13), may be summarized as including the following successive steps: a) forming of a peripheral groove (15, 15′) in the semiconductor substrate (13) on the side of a first surface of the semiconductor substrate (13); b) deposition of an oxygen-doped polysilicon layer (21, 21′), on top of and in contact with the bottom and the lateral walls of the peripheral groove (15, 15′) and with said first surface of the semiconductor substrate (13); c) local deposition of a glass layer (31, 31′), on the oxygen-doped polysilicon layer (21, 21′), the glass layer (31, 31′) extending in the peripheral groove (15, 15′) and further extending over a portion of said first surface of the semiconductor substrate (13); and d) etching of the oxygen-doped polysilicon layer (21, 21′) so that it extends on said first surface of the semiconductor substrate (13) beyond the glass layer (31, 31′).

The electronic power component forming method may include, between steps b) and c), a step e) of deposition of an electrically-insulating layer (29, 29′) on top of and in contact with the oxygen-doped polysilicon layer (21, 21′).

The electronic power component forming method may include, between steps c) and d), a step e) of deposition of an electrically-insulating layer (29, 29′) on top of and in contact with the glass layer (31, 31′) and a portion of the oxygen-doped polysilicon layer (21, 21′) not covered with the glass layer (31, 31′).

The electrically-insulating layer (29, 29′) may be etched, at the same time as the oxygen-doped polysilicon layer (21, 21′), during step d).

The deposition of the glass layer (31, 31′) during step c) may be performed by silk-screening.

The groove (15, 15′) may have a depth greater than 75 μm.

The oxygen-doped polysilicon layer (21, 21′) may have a thickness in the range from 0.1 μm to 2 μm.

An electronic power component (100; 200), may be summarized as including: a peripheral groove (15, 15′) formed in a semiconductor substrate (13) on the side of a first surface of the semiconductor substrate (13); an oxygen-doped polysilicon layer (21, 21′), formed on top of and in contact with the bottom and the lateral walls of the peripheral groove (15, 15′) and with said first surface of the semiconductor substrate (13); and a glass layer (31, 31′), formed on the oxygen-doped polysilicon layer (21, 21′), the glass layer (31, 31′) extending in the peripheral groove (15, 15′) and further extending on a portion of said first surface of the semiconductor substrate (13) and the oxygen-doped polysilicon layer (31, 31′) extending on said first surface of the semiconductor substrate (13) beyond the glass layer.

The electronic power component (100; 200) may include an electrically-insulating layer (29, 29′) between the oxygen-doped polysilicon layer (21, 21′) and the glass layer (31, 31′), the electrically-insulating layer (29, 29′) being in contact, by a first surface, with the oxygen-doped polysilicon layer (21, 21′) and, by a second surface opposite to the first surface, with the glass layer (31, 31′).

The electronic power component (100; 200) may include an electrically-insulating layer (29, 29′), the glass layer being in contact, by a first surface, with the electrically-insulating layer (29, 29′) and, by a second surface opposite to the first surface, with the oxygen-doped polysilicon layer (21, 21′) and the electrically-insulating layer (29, 29′) being in contact with a portion of the oxygen-doped polysilicon layer (21, 21′) not covered with the glass layer (31, 31′).

The groove (15, 15′) has a depth greater than 75 μm.

The oxygen-doped polysilicon layer (21, 21′) has a thickness in the range from 0.1 μm to 2 μm.

13. A power control circuit may be summarized as including an electronic power component.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure. CLAIMS

1. A method of forming an electronic power component, comprising:
forming a peripheral groove in a first surface of a semiconductor substrate;
depositing an oxygen-doped polysilicon layer, on top of and in contact with a bottom and a plurality of lateral walls of the peripheral groove and with the first surface of the semiconductor substrate;
locally depositing a glass layer, on the oxygen-doped polysilicon layer, the glass layer extending in the peripheral groove and further extending over a portion of the first surface of the semiconductor substrate; and
etching the oxygen-doped polysilicon layer so that it extends on the first surface of the semiconductor substrate beyond the glass layer.

2. The electronic power component forming method according to claim 1, comprising, between depositing an oxygen-doped polysilicon layer and locally depositing a glass layer, depositing an electrically-insulating layer on top of and in contact with the oxygen-doped polysilicon layer.

3. The electronic power component forming method according to claim 1, comprising, between locally depositing a glass layer and etching the oxygen-doped polysilicon layer, depositing an electrically-insulating layer on top of and in contact with the glass layer and a portion of the oxygen-doped polysilicon layer not covered with the glass layer.

4. The electronic power component forming method according to claim 2, wherein the electrically-insulating layer is etched, at the same time as the oxygen-doped polysilicon layer, during the etching the oxygen-doped polysilicon layer.

5. The electronic power component forming method according to claim 1, wherein the deposition of the glass layer is performed by silk-screening.

6. The electronic power component forming method according to claim 1, wherein the groove has a depth greater than 75 μm.

7. The electronic power component forming method according to claim 1, wherein the oxygen-doped polysilicon layer has a thickness in the range from 0.1 μm to 2 μm.

8. An electronic power component, comprising:
a peripheral groove in a semiconductor substrate on a side of a first surface of the semiconductor substrate;
an oxygen-doped polysilicon layer, on top of and in contact with a bottom and a lateral wall of the peripheral groove and with the first surface of the semiconductor substrate; and
a glass layer, on the oxygen-doped polysilicon layer, the glass layer extending in the peripheral groove and extending on a portion of the first surface of the semiconductor substrate and the oxygen-doped polysilicon layer extending on the first surface of the semiconductor substrate beyond the glass layer.

9. The electronic power component according to claim 8, comprising an electrically-insulating layer between the oxygen-doped polysilicon layer and the glass layer, the electrically-insulating layer being in contact, by a first surface, with the oxygen-doped polysilicon layer and, by a second surface opposite to the first surface, with the glass layer.

10. The electronic power component according to claim 8, comprising an electrically-insulating layer, the glass layer being in contact, by a first surface, with the electrically-insulating layer and, by a second surface opposite to the first surface, with the oxygen-doped polysilicon layer and the electrically-insulating layer being in contact with a portion of the oxygen-doped polysilicon layer not covered with the glass layer.

11. The electronic power component according to claim 8, wherein the groove has a depth greater than 75 μm.

12. The electronic power component according to claim 8, wherein the oxygen-doped polysilicon layer has a thickness in the range from 0.1 μm to 2 μm.

13. A method, comprising:
forming a groove in a first surface of a substrate;
forming an oxygen-doped polysilicon layer in the groove and on the first surface of the substrate;
forming an insulating layer on and in contact with the oxygen-doped polysilicon layer;
forming a glass layer on the oxygen-doped polysilicon layer; and
forming a conductive layer on the first surface of the substrate, the conductive layer being in contact with the oxygen-doped polysilicon layer.

14. The method according to claim 13, wherein the groove extends through a central portion of the substrate having a first doping concentration and an outer portion of the substrate having a second doping concentration different from the first doping concentration.

15. The method according to claim 14, wherein the outer portion of the substrate increases in a gradient from the central portion of the substrate to the first side of the substrate.

16. The method according to claim 14, wherein an interface between the outer portion of the substrate and the central portion of the substrate is a PN junction.

17. The method according to claim 13, comprising forming a doped region in the substrate coplanar with the first surface of the substrate.

18. The method according to claim 17, wherein the conductive layer is in contact with the doped region.

19. The method according to claim 13, wherein the glass layer is between the oxygen-doped polysilicon layer and the insulating layer.

20. The method according to claim 13, wherein the insulating layer is between the oxygen-doped polysilicon layer and the glass layer.
